(19) United States
(12) Patent Application Publication
(10) Pub. No.: US 2015/0006096 A1
(43) Pub. Date: Jan. 1, 2015

(54) System and Method for Estimating a Periodic Signal

(71) Applicant: Infineon Technologies AG, Neubiberg (DE)

(72) Inventors: Juergen Helmschmidt, Gilching (DE); Fabio Parodi, Genova (IT); Stephan Schoenfeldt, Hoehenkrichen-Siegertsbrunn (DE); Sergio Rossi, Genova (IT)

(21) Appl. No.: 13/929,284

(22) Filed: Jun. 27, 2013

(51) Int. Cl. G01R 22/00

(52) U.S. Cl. CPC G01R 22/00
USPC 702/66

(57) ABSTRACT

In accordance with an embodiment, a method of reconstructing a periodic signal includes receiving random electronic samples of the periodic signal from a sensing circuit, sorting, by a processor, the electronic samples in a sequential order to form ordered samples, and estimating, by the processor, a shape of the periodic signal based on the ordered samples

### TECHNICAL FIELD

The present disclosure relates generally to an electronic device, and more particularly to a system and method for estimating a periodic signal.

### BACKGROUND

Automatic meter reading (AMR) has been introduced by utility providers, such as energy, water or gas providers, for example, in order to be able to automatically collect consumption, diagnostic and status data from energy, water or gas metering devices. These data are transferred to a central database for billing, troubleshooting and analyzing, which makes information about consumption available almost on a real-time basis. This timely information coupled with analysis may help both utility providers and consumers to better control the use and production of electric energy, gas usage or water consumption.

Analog meters of previous generations, such as Ferraris analog counters that were used to measure electric power consumption, possessed a one-to-one physically reliable relationship between the energy consumption and the turning wheel inside the counter. Thus, it was simple matter for an electric power customer or electric utility company to monitor ongoing power consumption and the validity of the metered electric consumption. For example, the electric power customer can simply compare the meter readings listed on the electric bill with the actual meter reading. In systems that electronically implement automatic meter reading, it may be more difficult for the customer or service provider to verify whether the power consumption detected by the electronic meter and the billed power is in line with each other or whether the reported electric power consumption data logged or transmitted by the electronic meter has been modified or tampered with. Such tampering may be the result of a user attempting to manipulate the logged data in order to reduce utility bill, or the tampering may be a result of a supplier attempting to increase a customer's bill.

### SUMMARY OF THE INVENTION

In accordance with an embodiment, a method of reconstructing a periodic signal includes receiving random electronic samples of the periodic signal from a sensing circuit, sorting, by a processor, the electronic samples in a sequential order to form ordered samples, and estimating, by the processor, a shape of the periodic signal based on the ordered samples.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of a smart meter device;

FIGS. 2a-2b illustrate more detailed block diagrams of a smart meter device;

FIG. 3 illustrates a block diagram of embodiment metrology algorithms;

FIGS. 4a-b illustrates a block diagrams of embodiment methods;

FIGS. 5a-e illustrate waveform diagrams showing an embodiment reconstruction of a sinusoidal signal;

FIGS. 6a-c illustrate waveform diagrams showing an embodiment reconstruction of a distorted signal; and

FIG. 7 illustrates a block diagram of an embodiment processing system.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, a system and method for a smart electric meter that provides verifiable measurement data. The invention may also be applied, however, to other applications including, but not limited to electricity, gas and water meters, flow and energy meters in general, remote sensing systems, data logging applications, data processing systems, and other systems that provide verifiable recorded data.

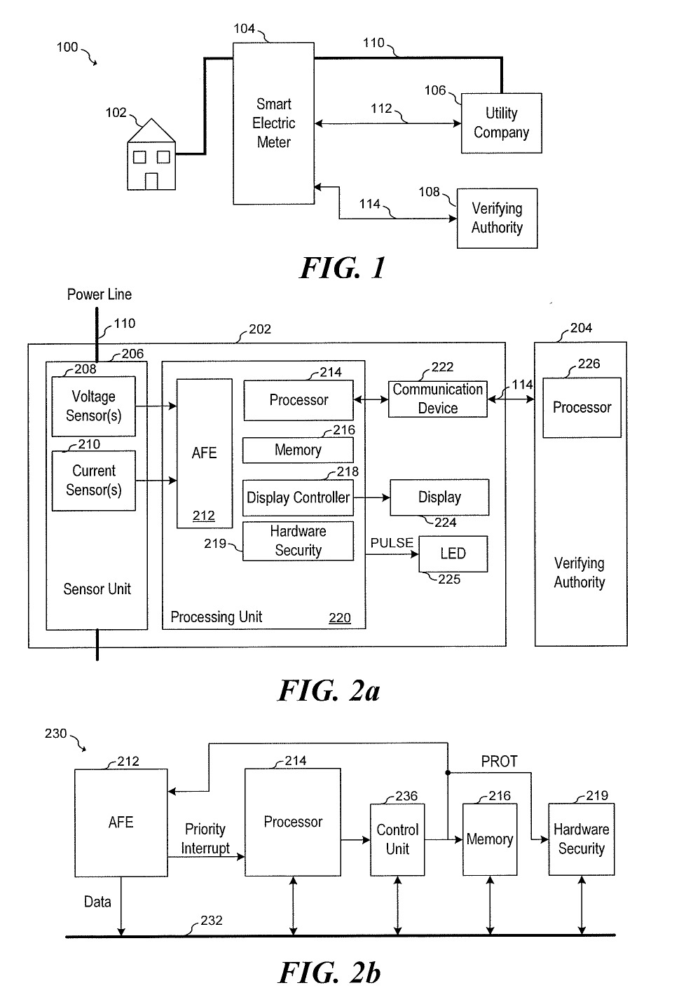

FIG. 1 illustrates an example power measurement scenario 100 according to an embodiment of the present invention. As shown, customer 102 receives power from utility company 106 via power line 110 and smart electric meter 104 that measures the power consumed by customer 102. Smart electric meter 104 may reside, for example, within a building or residence of the customer 102. In some embodiments, smart electric meter 104 is configured to switch on and off the power supply of the customer 102. Metering data is sent to the utility company via communication link 112. Communication link 112 may be a wireless communication link, a telephone link, a wired Internet link, a power line link, a dedicated wired link, or other communication link. During normal operation, smart electric meter 104 sends utility company 106 data that represents the amount of power consumed by customer 102. This data may be sent at predetermined intervals, and may represent values such as real power, reactive power, apparent power, power factor, harmonic power consumption, system status information and other data. Accordingly, utility company 106 may use this data for billing purposes and/or for the purposes of monitoring the overall integrity of the power distribution system. For example, utility company 106 may use power factor information and harmonic power consumption to determine the efficiency of power delivered to customer 102, and may adjust the power distribution system based on these received measurements.

In an embodiment, smart electric meter 104 is also in communication with verifying authority 108, which may be a public, private, or governmental organization tasked with verifying the integrity of the measurements made by smart electric meter 104. Situations in which measurements made by smart electric meter 104 may lose integrity are, for example, in situations where smart electric meter 104 has been damaged, or has been tampered with. Tampering may potentially occur on the part of both electric customer 102 and utility company 106. For example, customer 102 may tamper with electric smart meter 104 in order that measurement data sent by smart electric meter 104 under reports the amount of power consumed. Tampering by the customer 102 might include attempting to reprogram smart electric meter 104, or physically bypassing smart electric meter 104.

On the other hand, utility company 106 may be motivated to adjust smart electric meter 104 in order to report a higher electric consumption than was really consumed. Tampering by utility company 106 may include, for example, modifying the software, hardware and/or data within smart electric meter 104. In cases where utility company 106 provides and/or manufactures smart electric meter 104, software or hardware within smart electric meter may be specifically designed to falsify the actual amount of power consumed.

In embodiments of the present invention, there are a number of ways in which verifying authority 108 may verify the integrity of the measurements made by smart electric meter 104. One way that verification may be performed is by sending raw voltage and current measurements to verifying authority 108 in a controlled random fashion, meaning that a random sample is chosen by a method involving a random or pseudo-random component. As such, a small percentage, such as 1% or 2%, is sent to verifying authority on a time randomized or random time basis. In embodiments, this randomization may be implemented without any intermediate storage of data in unprotected memory such as RAM, flash etc., and without using other temporary or processed data stored in unprotected memory. In some embodiments, intermediate data may be written into protected SRAM.

In an embodiment, verifying authority 108 receives these randomly sent measurement samples, recalculates power consumption measurements, and compares the recalculated measurements with reported consumption measurements. In embodiments in which the randomly sent values are signed and/or encrypted, verifying authority 108 may first verify the signature and/or decrypt the measurements. If the recalculated consumption measurements are within a margin of error of the measurements reported by the smart meter and/or the utility, the reported measurements may be considered valid. If, on the other hand, the recalculated measurements are outside of the margin of error, then a possibility of tampering has been detected. In such embodiments, smart electric meter 104 is configured to electronically sign data samples using hardware and software that cannot be tampered with or modified. These electronically signed data samples may represent raw data measurements made by smart electric meter of currents and voltages on power line 110 before further processing is performed. Communication channel 114 may be implemented, for example, using a Universal Asynchronous Receiver-Transmitter (UART), serial communication interface, or a wireless or wire line network interface. In some embodiments, transmission of the random data blocks cannot be interrupted by any other blocks, devices or entities in the system. Electronic signatures may be generated, for example, using encrypted electronic signature techniques and methods known in the art. For example, data may be signed using hash values and/or encrypted using symmetric or asymmetric cryptographic algorithms such as the advanced encryption standard (AES), a Rivest, Shamir, & Adleman (RSA) algorithm, SHA1/256, Hamming Code, Message-Digest Algorithm (MD5) or elliptic curve cryptography (ECC) method.

Once verifying authority 108 has received electronically signed data, authority 108 may compare the received electronic we signed data with data received from utility company 106 or measurement data generated by smart electric meter 104. In embodiments in which electronically signed raw data is used by verifying authority 108 in order to verify the integrity of smart electric meter 104, measurement and metrology algorithms implemented by smart electric meter 104 are reproduced by verifying authority 108, and the results of these reconstructed measurements are compared to measurements produced by smart electric meter 104 and/or power measurements received by utility company 106. Tampering may become apparent, for example, if the reconstructed power measurements do not match, or are not within an acceptable margin of error or margin of deviation of measurements produced by smart electric meter 104, and or measurements reported by utility company 106. It should be understood that the embodiment scenario of FIG. 1 may also be applicable to other types of measurements. For example, in some embodiments, other utility types may be measured such as natural gas, water or any kind of consumed liquids or energy. Embodiment concepts may also be used to measure other variables and verify the measurements.

Due to the random sending of data, assuming a substantially constant power consumption, enough data are sent to reconstruct the averaged power consumption within a particular time frame. Given the random samples, the received waveform is reconstructed and measurement data is re-derived based on the reconstructed waveforms. Parameters such as root-mean-square (RMS) power consumption may be derived from the reconstructed waveforms and compared to data reported to utility company 106. In one example, the one cycle of raw data may contain from about 80 to about 160 samples. By transmitting 1% of raw data, on average about 1 to 2 samples of each cycle of raw data is transmitted. This means, that about 100 cycles or, at a line frequency of 50 Hz, 2 seconds would be needed to get one full approximated sine wave.

In an embodiment, smart electric meter 104 is configured such that random samples cannot be prevented from being sent. Randomly or pseudo-randomly generated values are used to decide whether or not a given sample is to be sent. In some embodiments, this random transmission of raw data, and the process by which measurement values are randomly selected for transmission, does not depend on the details of preceding data transmissions. Raw data may be packed and sent immediately after sample acquisition. There may be n acquisition time points per second, for example, depending on the given sampling rate of the particular analog-to-digital converter (ADC) that is used. Smart electric meter 104 may be configured to prevent the interruption of the sending of raw data sampled to verifying authority 108. In some embodiments, systems, methods and techniques may be incorporated, especially those relating the random transmission of raw data, that are described in U.S. patent application Ser. No. 13/428,718 entitled, “Method to Detect Tampering of Data,” filed on Mar. 23, 2012; and in U.S. patent application Ser. No. 13/459,772 entitled, “Method to Detect Tampering of Data,” filed on Apr. 30, 2012, which applications are incorporated herein by reference in their entirety.

As mentioned above, raw data measurement data may be signed and/or encrypted, before being sent verifying authority 108. Processed measurement data may be encrypted and sent as well. The same or different encryption methods might be used for raw data and for processed data. In some embodiments, the processing, signature generation, hashing and encryption of raw and processed data measurements may be performed by a processor running in a privileged mode. In some embodiments, systems and methods of privileged execution modes, as well as other systems and methods, may be used that are described in U.S. patent application Ser. No. 13/590,017 entitled, “System and Method for Processing Device with Differentiated Execution Mode,” filed on Aug. 20, 2012, and in U.S. patent application Ser. No. 13/904,957 entitled “System and Method for a Processing Device with a Priority Interrupt,” filed on May 29, 2013, which applications are incorporated herein by reference in their entirety.

FIG. 2a illustrates embodiment smart electric meter 202 coupled to verifying authority 204. Smart electric meter 202 includes sensor unit 206, processing unit 220, communication device 222 and display 224. Sensor unit 206 is coupled to power line 110 and includes one or more voltage sensors 208 and one or more current sensors 210. Each of voltage sensors 208 and current sensors 210 produces an analog signal that is coupled to analog front-end (AFE) 212 within processing unit 220. AFE 212 may include, for example, one or more analog to digital converters that converts the analog output from voltage sensors 208 and current sensors 210 to a digital representation. Processor 214 performs operations on data produced by AFE 212. These operations may include, for example, data logging, execution of metrology algorithms, encrypted signature generation of either raw data or measure data, and other system tasks. During operation, processor 214 may read and write data from and to memory 216. Communication device 222 is configured to transmit and receive data to and from verifying authority 204 and or the utility company (not shown). Communication device 222 may include, for example, a wireless and/or wire line interface. Example interfaces may include, but are not limited to near distance communication interfaces such as Wireless M-Bus, M-Bus, ZigBee, and Power Line Communication (PLC) interfaces, and far distance communication interfaces such as PSTN, GSM, UMTS, and WLAN.

In an embodiment, display 224 provides a visual interface that shows the amount of power measured by smart meter 202. Display 224 may include, for example, in liquid crystal display (LCD) that is controlled by display controller 218. Alternatively, other display types may be used and/or measured meter data may be fed into an in-house data communication network. Hardware security block 219 may be provided to provide hardware-based encryption support for encrypting and decrypting data, and generating verification signatures. In addition, hardware security block 219 may also provide hardware-based support to software-based encryption routines executed on processor 214. One such example of hardware-based support is a True Random Number Generator, the output of which may be used by encryption algorithms such as Elliptic Curve Cryptography (ECC) or by routines used to randomize the sending of raw data. In addition, hardware security block 219 may also contain hardware support for other random number generation algorithms. Hardware security block 219 may function, for example, as an accelerator or coprocessor or may implement an entire cryptographic algorithm in total.

Verifying authority 204 receives data from communication device 222 via communication channel 114. In some embodiments, verifying authority 204 may be implemented using, for example, a computer and/or processor 226. In some embodiments, verifying authority 204 may be coupled to smart meter 202 via a network such as a wide area network or the Internet. In some embodiments, smart meter 202 may also be configured to be in communication with a local area network (LAN), for example, via a Wi-Fi connection or a wired LAN connection, such as an Ethernet connection. In some embodiments, smart meter 202 may transmit power consumption measurements and statistics to electric customer 102 via a LAN, so that electric customer can monitor power usage.

In embodiments of the present invention, data that is subject to later verification, such as signed raw data and signed measurement data, is processed in a way that prevents tampering by non-trusted software and/or non-authorized users. One way in which this data is protected is by operating embodiment systems in a protected mode that allows writing to protected areas of memory and access to critical system resources by trusted hardware and software routines, but prevents access by non-trusted hardware and software. In embodiments, a priority interrupt generated by AFE 212 is used to place processor 214 in a protected mode. In this protected mode, processor 214 may write raw data generated by AFE 212 and perform trusted operations on this raw data. In some embodiments, the protected mode is realized via a non-maskable, nom-interruptible time slice of the processors operating time. This may be implemented using the highest interrupt level of a standard CPU processing engine. Once processor 214 is finished executing trusted software routines, the processor exits the protected mode and optionally secures various resources of processing unit 220 to prevent tampering. Securable resources of processing unit 220 may include, but are not limited to, write and/or read access to portions of random access memory (RAM), static random access memory (SRAM), nonvolatile memory such as flash memory, system configuration registers, configuration and access to various peripherals, test modes, and other system resources.

In an embodiment, data sent to customer 102 may include power consumption data that is derived based on raw samples provided by AFE 212. In some embodiments, these derived measurements are calculated using a fast metrology algorithm in conjunction with a slow metrology algorithm. The fast metrology algorithm may calculate, for example, zero crossing points of the voltages and currents measured by AFE 212 and provide intermediate calculations or variables that are then used by a slow metrology algorithm to calculate power consumption and other calculated variables. In an embodiment, a measurement routine is executed by processor 214 each time AFE 212 provides a sample. This may occur at a sampling rate of for example, 1 kHz, 2 kHz, 4 kHz, 8 kHz, or another sampling rate. In some embodiments, a pulse signal is provided that illuminates LED 225 at predetermined power consumption intervals. The time intervals at which LED 225 is illuminated may be used by customer 102 or verifying authority 108 to visually verify the accuracy and operation of the smart meter.

After a predetermined number of samples have been processed by the fast metrology algorithm, the slow metrology algorithm may be executed to determine a set of calculated variables such as power consumption, power factor, harmonic power and other calculated variables. In some embodiments, the slow metrology algorithm is executed after intermediate values from a full waveform cycle have been collected. In some embodiments, calculate routine is executed after between about 10 and 80 samples have been collected. Alternatively, the slow metrology algorithm may be executed after a number of samples outside of this range have been collected.

In embodiments of the present invention, data that is subject to later verification, such as signed raw data, signed measurement data and randomly transmitted data, is processed in a way that prevents tampering by non-trusted software and/or non-authorized users. One way in which this data is protected is by operating embodiment systems in a protected mode that allows writing to protected areas of memory and access to critical system resources by trusted hardware and software routines, but prevents access by non-trusted hardware and software. In embodiments, a priority interrupt generated by AFE 212 is used to place processor 214 in a protected mode. In this protected mode, processor 214 may write raw data generated by AFE 212 and perform trusted operations on this raw data. Once processor 214 is finished executing trusted software routines, the processor exits the protected mode and secures various resources of processing unit 220 to prevent tampering. Securable resources of processing unit 220 may include, but are not limited to, write and/or read access to portions of random access memory (RAM), static random access memory (SRAM), nonvolatile memory such as flash memory, system configuration registers, configuration and access to various peripherals, test modes, and other system resources.

The priority interrupt that places processor 214 in the protected mode may be implemented using the highest priority interrupt below reset. In some processing systems, this priority interrupt is a non-maskable interrupt (NMI). FIG. 2b illustrates a smart meter system 230 according to an embodiment of the present invention that further illustrates the hardware blocks involved in protected mode operation. As shown, smart meter system 230 includes, AFE 212, processor 214, control unit 236, memory 216 and bus 232. In embodiments, a priority interrupt is generated each time AFE 212 outputs a measurement sample, which can occur, for example, at sampling rates of between about 1 kHz to about 4 kHz in electric metering applications. This priority interrupt is received by processor 214 that, in turn, signals a request to control unit 236 indicating that protected mode of operation is needed.

Once control unit 236 receives notification to place system 230 into protected mode, AFE 212, memory 216 and hardware security block 219 are placed in a protected mode via signal PROT. In protected mode, portions of memory 216 that may otherwise be inaccessible are made accessible to processor 214 via bus 232. Examples of protected memory resources may include, for example, portions of SRAM that are used to temporarily store raw data samples, portions of SRAM that are used to compute encrypted data signatures, portions of non-volatile memory used to store private encryption keys, and portions of memory used to store trusted processing routines. In the protected mode access to AFE 212 and hardware security block 219 are allowed by the protected device.

Control unit 236 may also enable other system resources that are otherwise inaccessible during protected mode operation. For example, a watchdog timer (WDT) of the system may be made inaccessible from unprotected code to prevent system tampering via the assertion or frequent and unwanted resets. In addition, a system control unit (SCU), clock generation unit (CGU), configuration encryption unit (CEU), the real-time clock (RTC), the power mode unit (PMU) and the display unit may be secured during normal operation and made accessible during protected mode operation. Keeping the operation for these blocks protected helps to provide a more secure system since the SCU controls the switching between normal mode operation and secured mode operation, and the CGU and the CEU may be subject to tampering attacks. Securing the RTC and the PMU may prevent the system from being shut down during operation, and securing the display unit helps ensure that correct power consumption values are displayed.

As mentioned above, AFE 212 asserts a priority interrupt every time a new sample is ready, which could occur at intervals of 1 ms or less depending on the sample rate of AFE 212. For example, sampling rates of 2 KHz, 4 KHz and 8 KHz may be used. In some embodiments, samples may be synchronously aligned with the zero crossing point of the measured voltage waveform or sampling may be performed asynchronously. Higher and lower sampling rates may also be implemented depending on the particular system, specification and power requirements. In embodiments where a digital signature is assigned to sets of raw data samples, however, encryption or hashing processing may take a few seconds, which far exceeds the sampling interval for AFE 212.

In order to ensure privileged mode operation for encryption algorithms, or for routines requiring execution times exceeding the sampling interval of AFE 212, a semi-privileged interrupt mechanism is used. In an embodiment, a routine running under a privileged interrupt may assert a semi-privileged interrupt. This semi-privileged interrupt is one interrupt level lower than the privileged interrupt. Routines running in response to a semi-privileged interrupt may be executed in this privileged mode, and may access memory and system resources that are otherwise unavailable in a normal mode of operation. Execution of a routine running in a semi-privileged mode may be interrupted when the privileged interrupt is asserted. For example if an encryption algorithm is running in a semi-privileged mode, and AFE 212 asserts a privileged interrupt, execution of the semi-privileged mode is interrupted, and routines configured to process data provided by AFE 212 are executed under the priority interrupt. During this time, routines operating under the priority interrupt may call non-privileged software routines by exiting the privileged mode and waiting for execution of the non-privileged software routines to finish, after which execution then proceeds to operate in the privileged mode. When execution of the routine that was triggered by AFE 212 finishes, execution of the semi-privileged routine is resumed subject to periodic interruptions by routines operating under the priority interrupt. At the completion of the semi-privileged routine, a system call is made, the privilege mode is exited, and non-privileged user routines may be executed. In an embodiment, protected memory areas and other protected system resources are prevented from being accessed or tampered with by ensuring that the privileged mode has been exited in a manner that prevents access to secured areas is possible until the privileged interrupt is reasserted. This may be accomplished, for example, by having a routine running under the priority interrupt set the interrupt service routine (ISR) pointer of the semi-privileged interrupt to a trivial default position when semi-privileged routines finish operation.

In some embodiments, a routine running under a privileged interrupt and/or under a semi-privileged interrupt is used to determine when raw data is randomly sent to verifying authority 204. In one embodiment, a routine running under a semi-privileged interrupt determines which of the raw data samples are to be transmitted. In some embodiments, the routine selects about 1% of the raw data samples to be sent to verifying authority 204. In other embodiments, between about 2% and 5% are sent. Alternatively, other percentages of the raw data may be sent.

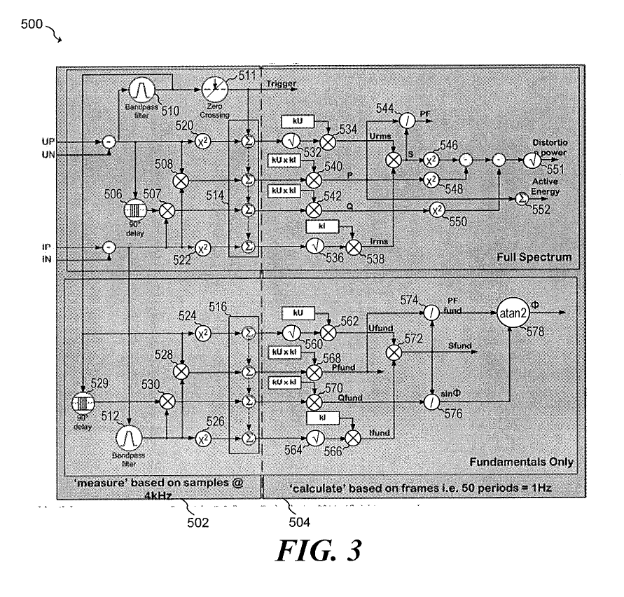

FIG. 3 illustrates a block diagram 500 that summarizes calculations made during fast metrology routine 502 and slow metrology routine 504. In an embodiment, voltage samples UP and UN representing a sensed line voltage, and current samples IP and IN representing a sensed line current are processed are bandpass filtered by filters 510 and 512, respectively. A squared input voltage calculated by scoring block 520, a squared input current calculated by scoring block 522, a real power calculated by multiplication block 508, and reactive power calculated by 90° phase shift block 506 and multiplication block 507 are determined to provide full spectrum power measurements.

For power measurements that operate only on the waveform, squaring block 524 is used to calculate a squared fundamental voltage, scoring block 526 is used to calculate a squared filtered current input, multiplication block 528 is used to calculate a real fundamental power, and phase shift block 529 and multiplication block 530 are used to calculate a reactive power at the fundamental frequency. Each of these power measurements calculated by fast metrology routine 502 or accumulated using accumulator 514 for full-spectrum measurements and accumulator 516 for fundamental measurements. At the end of each sine wave cycle, as detected by zero crossing detector 511 at the output of filter 510, the contents of accumulators 514 and 516 are transferred to slow metrology routine 504. In some embodiments, the contents of accumulators 514 and 516 are reset at the end of each voltage cycle.

In an embodiment, slow metrology routine 504 performs calculations at the end of a predetermined number of sine wave cycles. For example, in one embodiment slow metrology routine 504 operates at a rate of 1 Hz, or every 50 sine wave cycles for power systems in Europe, or every 60 sine wave cycles for power systems in the United States. In alternative embodiments of the present invention slow metrology algorithm 504 may operate at different intervals. In an embodiment, a full-spectrum root-mean-square (RMS) measurement of the input voltage is calculated by taking the square root of the accumulated square voltage measurement and scaling with scale factor kU to produce variable Urms via square root block 532 and multiplier 534. Likewise, a full-spectrum RMS measurement of the input current is calculated by taking the square root of the accumulated square current measurement and scaling with scale factor kI to produce variable Irms using square root block 536 and multiplier 538. Full spectrum real power P is calculated using multiplier 540 and scale factors Ku and KI, and full spectrum reactive power is calculated using multiplier 542 and scale factors Ku and KI. The full spectrum power factor is calculated using division block 544, the output distortion power is calculated using squaring blocks 546, 548 and 550 and square root block 551, and the full spectrum active energy is calculated using summation block 552.

The fundamental RMS voltage is calculated using square root block 560 and multiplier 562 to apply scale factor KU, and the fundamental RMS current is calculated using square root block 564 and multiplier 566 to apply scale factor KI. The fundamental real power Pfund is calculated using multiplier 568 to apply scale factor KU and KI, and the fundamental reactive power Qfund is calculated using multiplier 570. Apparent power Sfund is calculated using multiplier 572, the fundamental power factor PF fund is calculated using divider 574, and the sine of the phase angle between the voltage and the current waveforms is calculated using division block 576. Arctangent block 578 is used to calculate the phase angle between the voltage and current waveforms. It should be understood that the example calculations illustrated in block diagram 500 is just one of many example embodiments. In alternative embodiments of present invention, different measurements may be calculated using different implementations. For example, in some systems, power measurements may be made only at fundamental frequencies, or power measurements may be made only using full-spectrum measurements.

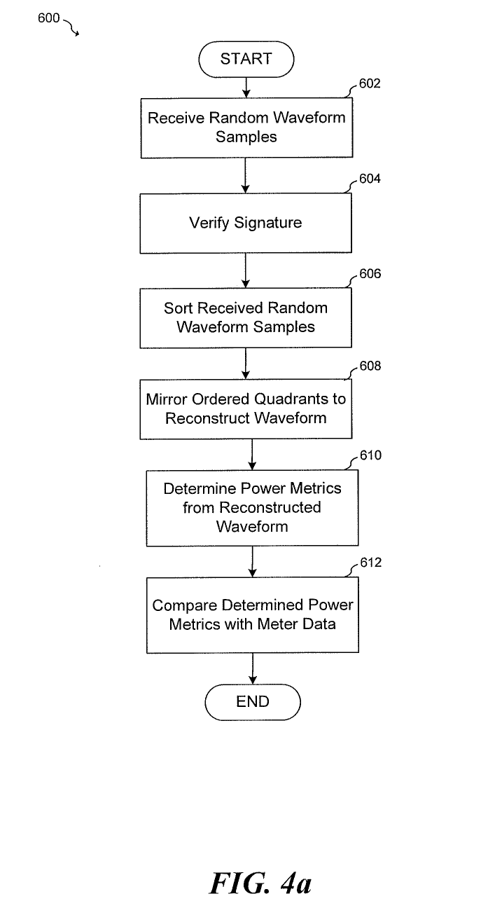

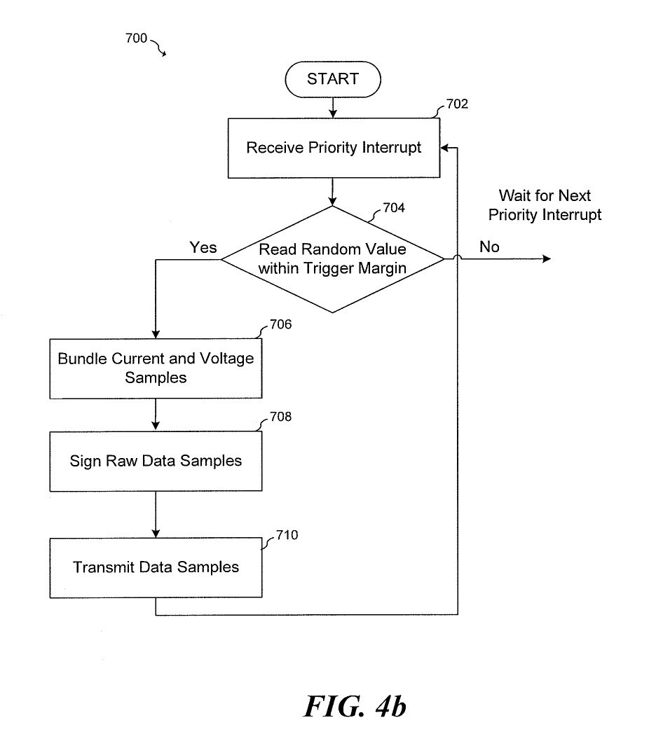

As mentioned above, raw data samples may be sent to verifying authority 108 at random time intervals. Using these random samples, verifying authority 108 may reconstruct or estimate the raw voltage and current waveforms and re-create calculated measurement data. FIG. 4a illustrates a block diagram 600 of an embodiment method that may be used by verifying authority 108 to reconstruct the randomly sampled data points. In step 602, the random waveform samples are received. These random waveform samples may be received, for example, via communication channel 114. In some embodiments, the received random waveform samples are stored in a memory using, for example, a processor. Next, if the randomly sampled data was signed using an encryption signature, this encryption signature is verified in optional step 604, which may be omitted. In an embodiment, signature verification routines known in the art may be used depending on encryption method used to create the signature.

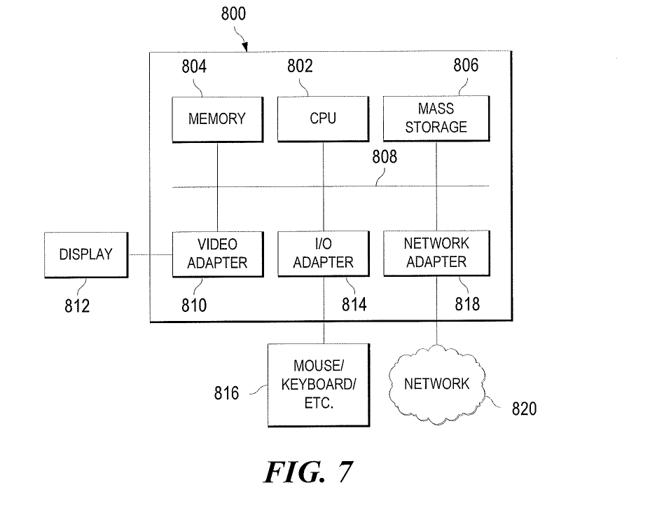

Next, the set of randomly sampled waveform samples are sorted in numerical order in step 606 to determine the first and third quadrants of the waveform. In some embodiments, the first and fourth quadrants, the second and third quadrants, or the second and fourth quadrants may be determined in the manner. Such an ordering may be done using sorting algorithms known in the art such as bubble sort, quicksort, binary tree sort, combsort, or a mergesort algorithm. Next, in step 608 the recovered quadrants are mirrored in order to reconstruct a complete period of the voltage and current waveforms. Such mirroring may be implemented by copying, reordering and concatenating sorted data points. Once at least one complete cycle of the waveform has been determined, power metrics, such as those calculated by the fast and slow metrology routines described with respect to FIG. 7 hereinabove may be re-created to determine an estimated set of power metrics in step 610. In some embodiments, about one second of data is collected (i.e., 50-60 cycles of data) before applying the slow metrology algorithm. In other embodiments, power metrics may be determined by applying spectral analysis or other techniques to determine real and apparent power, power factor, harmonic power, and the like. For example, a Fast Fourier Transform (FFT) or other algorithm known in the art may be used to accomplish this. The determined power metrics may be compared with actual meter data that was transmitted by the smart meter during the time in which the random samples were taken in step 612. Samples might be pre-smoothed by algorithms such as a method of least squares using the assumed fundamental sine wave as reference and the highest sample as peak of the sine wave. This may be repeated assuming a certain small percentage for the first, second and succeeding harmonics leading to a best fit algorithm that covers the fundamental plus a selection of basic harmonics.

FIG. 4b illustrates an embodiment method 700 that may be used by processing unit 220 to determine which data points are to be generated and send via communication device 222. In an embodiment, a priority interrupt is received by processor 214 in step 702. Next, in step 704, a random value is generated and compared with a trigger margin. If the random value is not within the trigger margin, the process waits until the next priority interrupt is received in step 702. If the random value is within the trigger margin, current and voltage samples are bundled for transmission in step 706. These values may be signed with a hash or encryption signature in optional step 708. In some embodiments, step 708 may be omitted. Once the current and voltage samples have been bundled and/or signed, they are transmitted in step 710.

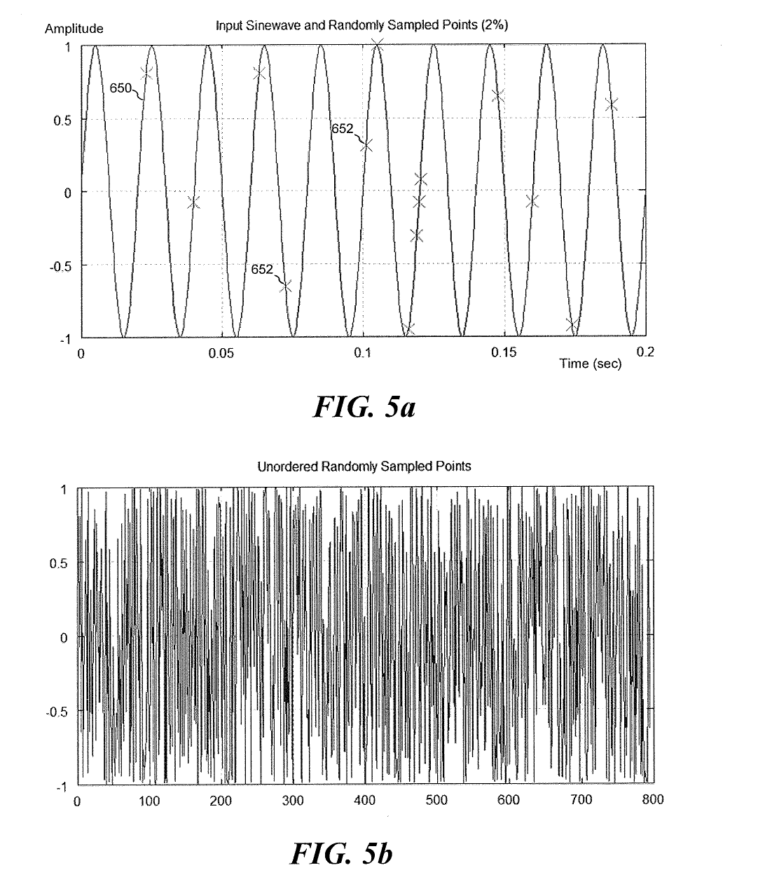

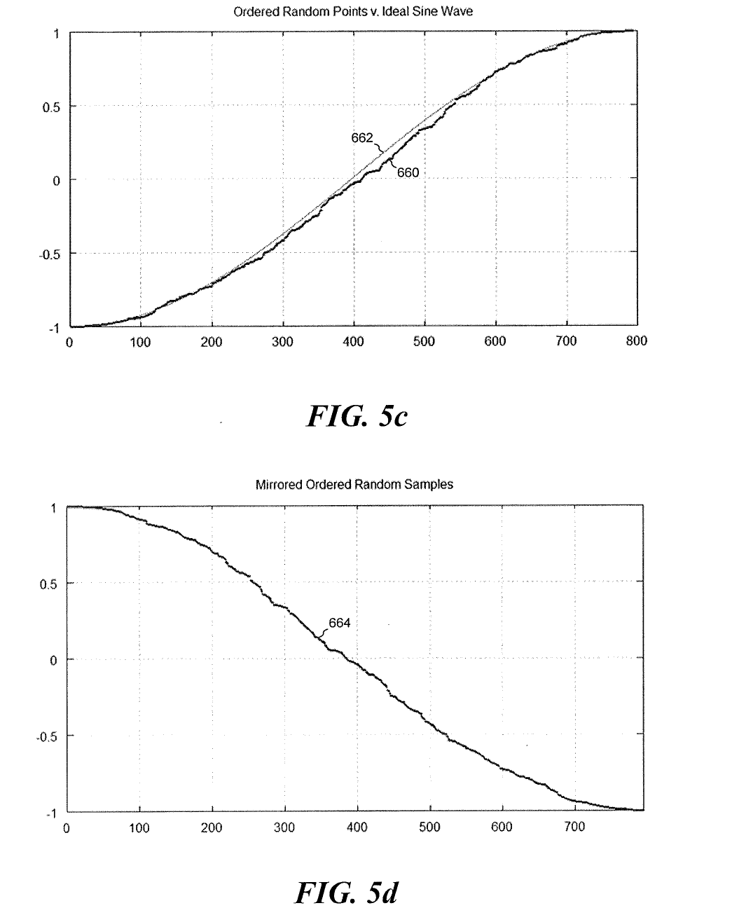

In some embodiments, the random samples are taken over a period of a few seconds. For example, in one embodiment, between 2% and 5% of the raw data samples are randomly selected by the smart meter for transmission over a period of between about 10 seconds and 15 seconds. Alternatively, other random data percentages and measurement intervals may be used. FIG. 5a illustrates a waveform representing an input sine wave 650 and randomly sampled data points 652. In the illustrated example, 2% of the waveform samples are randomly selected for transmission. FIG. 5b illustrates a waveform diagram showing a plot of the randomly sampled points. As mentioned above once the randomly sampled points are received, these points or ordered according to numerical value. FIG. 5c illustrates a plot of ordered data samples 660 as compared to the fourth and first quadrants of an ideal sine wave 662. It should be understood that in some embodiments of the present invention samples are sorted for both voltage waveform values and for current waveform values. FIG. 5d illustrates a waveform plot 664 of mirrored random samples, which are generated by reversing the order of waveform 660 illustrated in FIG. 5c. FIG. 5e illustrates a reconstructed waveform 666 that was created by replicating and concatenating ordered random samples.

In embodiments, the verifying authority may receive two sets of samples: current samples and voltage samples in order to recalculate power measurements. For simplicity of illustration, however, only a single waveform is illustrated in FIGS. 5a-e. Depending on the specific implementation of AFE 212, corresponding voltage and current samples may have a sampling time delay with respect to each other. This time delay may be due to processing delay, transmission delay, or differences in sampling times implemented by AFE 212. For example, in some embodiments, AFE 212 may comprise a single A/D converter that is multiplexed between various current and voltage channels. In such embodiments, current and voltage samples may have a fixed time offset. This fixed time offset may be taken into consideration by verifying authority 108 in the calculation of the phase difference between the voltage and current waveforms. Using this fixed time offset, the verifying authority may also estimate the power factor (PF) based on the reconstructed waveform. In an embodiment, the power factor may be determined by estimating the phase shift between reconstructed voltage and current waveforms.

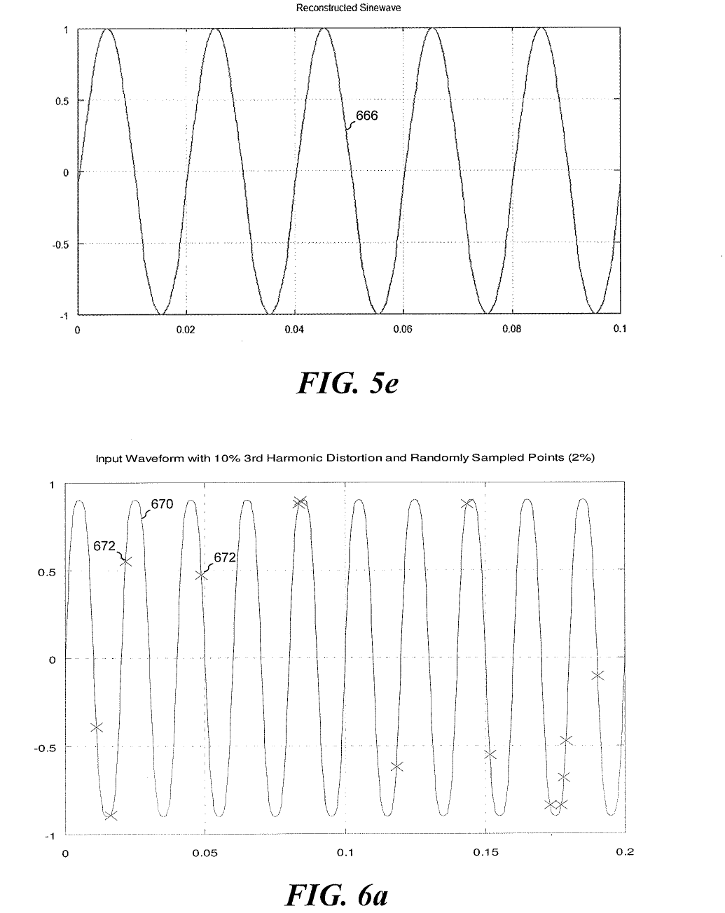

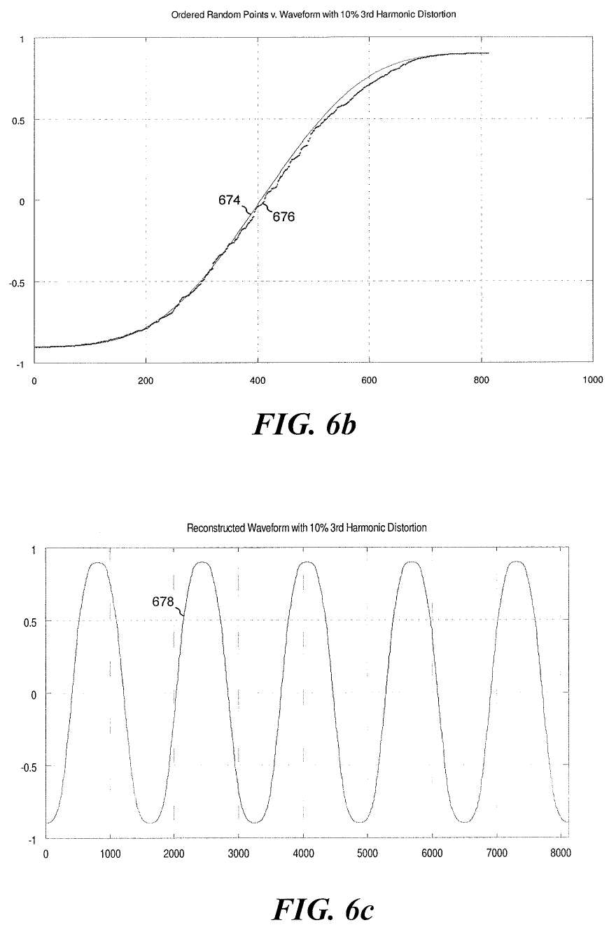

FIGS. 6a-c illustrate waveform diagrams showing the reconstruction of a distorted waveform. FIG. 6a shows input waveform 670, which is a sinewave that has been subject to 10% 3^{rd} harmonic distortion and its corresponding randomly sampled points 672. FIG. 6b shows a comparison between input distorted sinewave 674 and ordered randomly sampled points 676, and FIG. 6c illustrates the corresponding reconstructed waveform 678.

Referring now to FIG. 7, a block diagram of a processing system 800 is provided in accordance with an embodiment of the present invention. The processing system 800 depicts a general-purpose platform and the general components and functionality that may be used to implement portions of the smart meter and/or a computer or processing device used by the Authority. The processing system 800 may include, for example, a central processing unit (CPU) 802, memory 804, and a mass storage device 806 connected to a bus 808 configured to perform the processes discussed above. The processing system 800 may further include, if desired or needed, a video adapter 810 to provide connectivity to a local display 812 and an input-output (I/O) Adapter 814 to provide an input/output interface for one or more input/output devices 816, such as a mouse, a keyboard, printer, tape drive, CD drive, or the like.

The processing system 800 also includes a network interface 818, which may be implemented using a network adaptor configured to be coupled to a wired link, such as an Ethernet cable or the like, and/or a wireless/cellular link for communications with a network 820. The network interface 818 may also comprise a suitable receiver and transmitter for wireless communications. It should be noted that the processing system 800 may include other components. For example, the processing system 800 may include power supplies, cables, a motherboard, removable storage media, cases, and the like. These other components, although not shown, are considered part of the processing system 800.

In accordance with an embodiment, a method of reconstructing a periodic signal includes receiving random electronic samples of the periodic signal from a sensing circuit, sorting, by a processor, the electronic samples in a sequential order to form ordered samples, and estimating, by the processor, a shape of the periodic signal based on the ordered samples. In some embodiments, the sequential order may be an ascending order and/or a descending order. The sensing circuit may be, for example, a utility meter or other device.

In an embodiment, sorting includes sorting the electronic samples in ordered quadrants and estimating includes mirroring the ordered quadrants and concatenating the mirrored ordered quadrants to the ordered quadrants to form a full period of the periodic signal. The ordered quadrants may include, for example, a first quadrant and a fourth quadrant, and the mirrored ordered quadrants may include, for example, a second quadrant and a third quadrant.

Estimating may include forming a mirrored set of ordered samples by reversing an order of the ordered samples, concatenating the mirrored set of ordered samples to the ordered samples. In some embodiments, the periodic signal includes a voltage waveform and a current waveform, and the random electronic samples each include a voltage sample and a corresponding current sample. The method may further include determining electric power consumption metrics based on the voltage waveform and current waveform.

In an embodiment, estimating includes using a method of least squares to estimate a frequency, amplitude and phase of a fundamental component of the periodic signal. Furthermore, the method of least squares may be used to estimate an amplitude and phase of at least one harmonic component of the periodic signal.

In accordance with a further embodiment, a system includes a memory and a processor configured to receive random electronic samples of a periodic signal from a sensing circuit, store the random electronic samples in the memory, sort the electronic samples in a sequential order to form ordered samples, and estimate a shape of the periodic signal based on the ordered samples. In some embodiments, the sequential order may be an ascending order and/or a descending order.

In an embodiment, the processor is configured to sort the electronic samples in ordered quadrants and estimate the shape of the periodic signal by mirroring the ordered quadrants and concatenating the mirrored ordered quadrants to the ordered quadrants to form a full period of the periodic signal. The processor may be further configured to form a mirrored set of ordered samples by reversing an order of the ordered samples and concatenating the mirrored set of ordered samples to the ordered samples. In some embodiments, the random electronic samples of the periodic signal may include an encrypted verification signature, and the processor is further configured to verify the encrypted verification signature.

In an embodiment, the sensing circuit includes a utility meter, the random electronic samples include raw measurement data measured by the utility meter, and the processor is further configured to derive calculated measurement data from the raw measurement data. Moreover, the processor may be further configured to compare the calculated measurement data to calculated data generated by the utility meter.

In an embodiment, the periodic signal includes a voltage waveform and a current waveform, the random electronic samples each include a voltage sample and a corresponding current sample, and the processor is further configured to determine electric power consumption metrics based on the voltage waveform and current waveform.

In accordance with a further embodiment, a method of verifying measurements made by an electric utility meter include receiving time randomized raw measurement samples of an electric power waveform from the electric utility meter, sorting, by a processor, the time randomized raw measurement samples in a sequential order to form ordered samples, estimating, by the processor, a shape of the electric power waveform based on the ordered samples, deriving power consumption data based on the estimated shape of the electric power waveform, and comparing the derived power consumption data with power consumption data reported by the electric utility meter. The electric power waveform may include a voltage waveform and a current waveform, and the time randomized raw measurement samples may each include a voltage sample and a corresponding current sample. Moreover, the time randomized raw measurement samples may represent between 1% and 5% of raw measurement samples measured by the electric utility meter.

In an embodiment, the time randomized raw measurement samples further include an encrypted verification signature and the method further includes verifying the encrypted verification signature.

An advantage of embodiments includes the ability for a third party to securely verify the validity of metered data. Another advantage includes the ability to secure data using routines of varying lengths of time without tampering by unauthorized users and malicious software. Further advantages include the ability to detect meters have dropped out and/or have been shut down, as well as the ability to precisely network malfunctions based on the detection of meters that are no longer sending data. Another advantage includes the ability to estimate power consumption for a selected region by aggregating random data received from different meters. The aggregation of random data may also be used to estimate the distribution of reactive power over a region and determine the origins of such reactive power.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description.

What is claimed is:

1. A method of reconstructing a periodic signal comprising:
receiving random electronic samples of the periodic signal from a sensing circuit;
sorting, by a processor, the electronic samples in a sequential order to form ordered samples; and
estimating, by the processor, a shape of the periodic signal based on the ordered samples.

2. The method of claim 1, wherein the sequential order is an ascending order.

3. The method of claim 1, wherein:
sorting comprises sorting the electronic samples in ordered quadrants; and
estimating comprises mirroring the ordered quadrants and concatenating the mirrored ordered quadrants to the ordered quadrants to form a full period of the periodic signal.

4. The method of claim 3, wherein the ordered quadrants comprise a first quadrant and a fourth quadrant, and the mirrored ordered quadrants comprises a second quadrant and a third quadrant.

5. The method of claim 1, wherein estimating comprises:
forming a mirrored set of ordered samples by reversing an order of the ordered samples; and
concatenating the mirrored set of ordered samples to the ordered samples.

6. The method of claim 1, wherein:
the periodic signal comprises a voltage waveform and a current waveform; and
the random electronic samples each comprise a voltage sample and a corresponding current sample.

7. The method of claim 6, further comprising determining electric power consumption metrics based on the voltage waveform and current waveform.

8. The method of claim 1, wherein the sensing circuit comprises a utility meter.

9. The method of claim 1, wherein estimating comprises using a method of least squares to estimate a frequency, amplitude and phase of a fundamental component of the periodic signal.

10. The method of claim 9, further comprising using the method of least squares to estimate an amplitude and phase of at least one harmonic component of the periodic signal.

11. A system comprising:
a memory; and
a processor configured to
receive random electronic samples of a periodic signal from a sensing circuit,
store the random electronic samples in the memory,
sort the electronic samples in a sequential order to form ordered samples, and
estimate a shape of the periodic signal based on the ordered samples.

12. The system of claim 11, wherein the sequential order is an ascending order.

13. The system of claim 11, wherein the processor is configured to:
sort the electronic samples in ordered quadrants; and
estimate the shape of the periodic signal by mirroring the ordered quadrants and concatenating the mirrored ordered quadrants to the ordered quadrants to form a full period of the periodic signal.

14. The system of claim 11, wherein the processor is configured to form a mirrored set of ordered samples by reversing an order of the ordered samples and concatenating the mirrored set of ordered samples to the ordered samples.

15. The system of claim 11, wherein:
the random electronic samples of the periodic signal comprise an encrypted verification signature; and
the processor is further configured to verify the encrypted verification signature.

16. The system of claim 11, wherein:
the sensing circuit comprises a utility meter;
the random electronic samples comprise raw measurement data measured by the utility meter; and
the processor is further configured to derive calculated measurement data from the raw measurement data.

17. The system of claim 16, wherein the processor is further configured to compare the calculated measurement data to calculated data generated by the utility meter.

18. The system of claim 16, wherein:
the periodic signal comprises a voltage waveform and a current waveform;
the random electronic samples each comprise a voltage sample and a corresponding current sample; and
the processor is further configured to determine electric power consumption metrics based on the voltage waveform and current waveform.

19. A method of verifying measurements made by an electric utility meter, the method comprising:
receiving time randomized raw measurement samples of an electric power waveform from the electric utility meter;
sorting, by a processor, the time randomized raw measurement samples in a sequential order to form ordered samples;
estimating, by the processor, a shape of the electric power waveform based on the ordered samples;
deriving power consumption data based on the estimated shape of the electric power waveform; and
comparing the derived power consumption data with power consumption data reported by the electric utility meter.

20. The method of claim 19, wherein the time randomized raw measurement samples represent between 1% and 5% of raw measurement samples measured by the electric utility meter.
